(19) United States
(12) Patent Application Publication
(10) Pub. No.: US 2018/0090544 A1
(43) Pub. Date: Mar. 29, 2018

(54) DISPLAY DEVICE

(71) Applicant: Japan Display Inc., Tokyo (JP)

(72) Inventor: Masakazu GUNJI, Tokyo (JP)

(21) Appl. No.: 15/700,544

(22) Filed: Sep. 11, 2017

(30) Foreign Application Priority Data
Sep. 29, 2016 (JP) 2016-190736

(51) Int. Cl. H01L 27/32; H01L 51/52; G06F 3/041; G06F 3/044

(52) U.S. Cl. CPC H01L 27/323; H01L 51/5206; H01L 27/3248; H01L 27/3276; G06F 2203/04103; G06F 3/044; H01L 2227/323; G06F 3/0416; G06F 3/0412

(57) ABSTRACT

A display device includes scanning lines extending in a first direction and arrayed in a second direction on a first insulating surface; signal lines extending in a third direction and arrayed in a fourth direction on a second insulating surface; pixel electrodes provided in correspondence with intersections of the scanning lines and the signal lines; first touch lines extending in the first direction and arrayed in the second direction on the first insulating surface; second touch lines extending in the third direction and arrayed in the fourth direction on the second insulating surface; a first touch electrode on a third insulating surface, between pixel electrodes adjacent to each other, and connected with the first touch line; and a second touch electrode on the third insulating surface, between pixel electrodes adjacent to each other, and connected with the second touch line.

### CROSS REFERENCE TO RELATED APPLICATIONS

This application is based upon and claims the benefit of priority from the prior Japanese Patent Application No. 2016-190736, filed on Sep. 29, 2016, the entire contents of which are incorporated herein by reference.

### FIELD

An embodiment according to the present invention relates to a display device.

### BACKGROUND

As display devices usable for electric appliances and electronic devices, a liquid crystal display device using an electro-optical effect of a liquid crystal material and an organic EL (electroluminescence) display device including an organic electroluminescence (EL) element have been developed and put into actual products. In the meantime, a touch panel, which is a display device including a display element and a touch sensor provided on the display element, has been rapidly spread recently. Such a touch panel is now indispensable for mobile information terminals such as smartphones and the like, and is progressively developed worldwide for further improvement in the information society.

Methods for manufacturing such a touch panel are classified into two systems: one is an out-cell system, by which a touch sensor is manufactured separately from a display device and then the touch sensor and the display device are bonded together, and the other is an in-cell system, by which a touch panel is incorporated into a display device. Japanese Laid-Open Patent Publication No. 2012-212076 discloses a structure of a display device including a touch sensor.

### SUMMARY

An embodiment according to the present invention provides a display device including a plurality of scanning lines provided on a first insulating surface, the plurality of scanning lines extending in a first direction and arrayed in a second direction crossing the first direction; a plurality of signal lines provided on a second insulating surface provided on first insulating surface, the plurality of signal lines extending in a third direction crossing the first direction and arrayed in a fourth direction crossing the third direction; a plurality of pixel electrodes respectively provided in correspondence with intersections of the plurality of scanning lines and the plurality of signal lines; a plurality of first touch lines provided on the first insulating surface, the plurality of first touch lines extending in the first direction and arrayed in the second direction; a plurality of second touch lines provided on the second insulating surface, the plurality of second touch lines extending in the third direction and arrayed in the fourth direction; a first touch electrode provided on a third insulating surface provided on the second insulating surface, the first touch electrode being provided between pixel electrodes adjacent to each other as seen in a plan view, among the plurality of pixel electrodes, and electrically connected with at least one of the first touch lines; and a second touch electrode provided on the third insulating surface, the second touch electrode being provided between pixel electrodes adjacent to each other as seen in a plan view, among the plurality of pixel electrodes, and electrically connected with at least one of the second touch lines.

### BRIEF EXPLANATION OF DRAWINGS

FIG. 1A is a plan view showing a structure of a display device in an embodiment according to the present invention;

FIG. 1B is a plan view showing a part of a display region of the display device in an embodiment according to the present invention;

FIG. 2 is a plan view of a part of the display region of the display device in an embodiment according to the present invention;

FIG. 3 is a perspective view showing the structure of the display device in an embodiment according to the present invention;

FIG. 4 is a cross-sectional view showing the structure of the display device in an embodiment according to the present invention;

FIG. 5 is a cross-sectional view showing a method for manufacturing the display device in an embodiment according to the present invention;

FIG. 6 is a cross-sectional view showing the method for manufacturing the display device in an embodiment according to the present invention;

FIG. 7 is a cross-sectional view showing the method for manufacturing the display device in an embodiment according to the present invention;

FIG. 8 is a cross-sectional view showing the method for manufacturing the display device in an embodiment according to the present invention;

FIG. 9 is a cross-sectional view showing the method for manufacturing the display device in an embodiment according to the present invention;

FIG. 10 is a cross-sectional view showing the method for manufacturing the display device in an embodiment according to the present invention;

FIG. 11 is a cross-sectional view showing the method for manufacturing the display device in an embodiment according to the present invention;

FIG. 12 is a plan view of a part of a display region of a display device in an embodiment according to the present invention;

FIG. 13 is a cross-sectional view showing a structure of the display device in an embodiment according to the present invention;

FIG. 14 is a plan view showing a structure of the display device in an embodiment according to the present invention;

FIG. 15 is a plan view showing a structure of a display device in an embodiment according to the present invention;

FIG. 16 is a plan view showing a structure of a display device in an embodiment according to the present invention; and

FIG. 17 is a plan view showing a structure of a display device in an embodiment according to the present invention.

### DESCRIPTION OF EMBODIMENTS

Hereinafter, embodiments according to the present invention will be described with reference to the drawings. This disclosure merely provides an example, and modifications or alterations thereof readily conceivable by a person of ordinary skill in the art without departing from the gist of the present invention are duly encompassed in the scope of the present invention. In the drawings, components may be shown schematically regarding the width, thickness, shape and the like, instead of being shown in accordance with the actual sizes, for the sake of clearer illustration. The drawings are merely examples and do not limit the interpretations of the present invention in any way. In the specification and the drawings, components that have substantially the same functions as those described before with reference to a previous drawing(s) bear the identical reference signs thereto (or identical numerals with “a”, “b” or the like provided after the numerals), and detailed descriptions thereof may be omitted. The words “first”, “second” or the like provided for components are used merely to distinguish the components from each other, and do not have any further meaning unless otherwise specified.

In the specification and the claims, an expression that a component or a region is “on” another component or region encompasses a case where such a component or region is in direct contact with the another component or region and also a case where such a component is above or below the another component or region, namely, a case where still another component or region is provided between such a component or region and the another component or region, unless otherwise specified.

In this specification, the terms “conductive layer”, “electrode” and “line” refer to substantially the same element and are replaceable in accordance with the situation.

There are cases where for manufacturing a touch panel, a new line or electrode for a touch sensor is required. This may undesirably increase the number of manufacturing steps of the touch panel or decrease the detection precision of the touch sensor.

An embodiment of the present invention described below discloses a display device suppressing the process load imposed to form a touch sensor from increasing while improving the detection precision.

### Embodiment 1

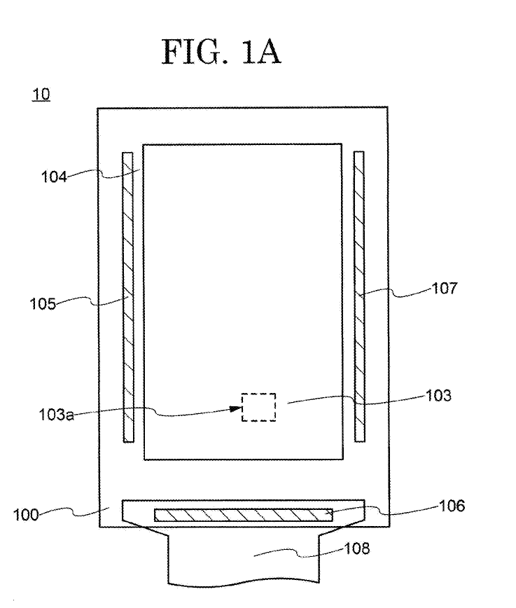

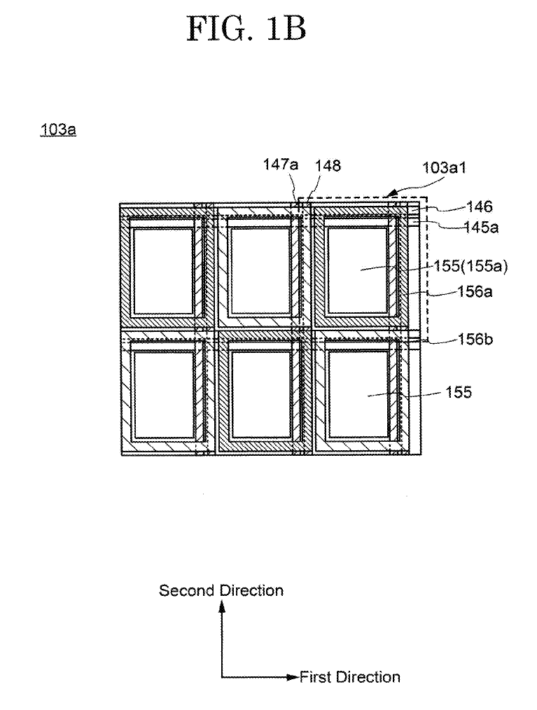

FIG. 1A and FIG. 1B shows a display device 10 in embodiment 1 according to the present invention. FIG. 1A is a plan view of the display device 10.

### (1. Structure of the Display Device)

As shown in FIG. 1A, the display device 10 includes a substrate 100, a display region 103 including pixels, a peripheral region 104, a driving circuit 105 having a function of a gate driver, a driving circuit 106 having a function of a source driver, a touch sensor driving circuit 107, and a flexible printed circuit 108.

### (1-1. Structure of the Touch Sensor)

FIG. 1B is a plan view of a display region 103a, which is a part of the display region 103 shown in FIG. 1A. The display region 103a includes scanning lines (gate lines) 145a, signal lines (source lines) 147a, pixel electrodes 155, first touch lines 146, second touch lines 148, first touch electrodes 156a and second touch electrodes 156b. The first touch lines 146, the second touch lines 148, the first touch electrodes 156a and the second touch electrodes 156b are included in a touch sensor. The scanning lines 145a and the first touch lines 146 extend in a shorter side direction of the pixel electrode 155 (the shorter side direction will be referred to as, for example, a “first direction”), and are arrayed in a longer side direction of the pixel electrode 155 crossing the first direction (e.g., perpendicularly crossing the first direction) (the longer side direction will be referred to as, for example, a “second direction”). The signal lines 147a and the second touch lines 148 extend in the second direction perpendicular to the first direction, and are arrayed in the first direction. The signal lines 147a and the second touch lines 148 are not limited to extending in the second direction, and may extend in a direction crossing the first direction but different from the second direction (such a direction will be referred to as, for example, a “third direction”). In this case, the signal lines 147a and the second touch lines 148 are arrayed in a direction crossing the third direction (such a direction will be referred to as, for example, a “fourth direction”).

The scanning lines 145a, the first touch lines 146, the signal lines 147a and the second touch lines 148 are provided below the pixel electrodes 155, the first touch electrodes 156a and the second touch electrodes 156b. The first touch electrodes 156a each have a function of a transmission electrode of the touch sensor, and the second touch electrodes 156b each have a function of a receiving electrode of the touch sensor.

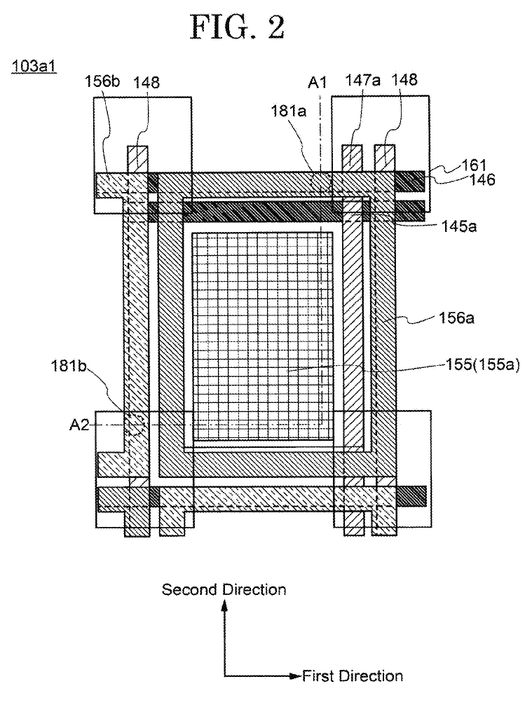

As shown in FIG. 1B, a display region 103a1 in the display region 103 includes a pixel electrode 155a. FIG. 2 is a plan view of the display region 103a1. As shown in FIG. 2, the first touch electrode 156a and the second touch electrode 156b are provided between the pixel electrode 155a and a pixel electrode 155 adjacent to the pixel electrode 155a. The first touch electrode 156a and the second touch electrode 156b are each provided to surround the pixel electrode 155. A plurality of pixel electrodes 155 are respectively provided in correspondence with intersections of the plurality of scanning lines 145a and the plurality of signal lines 147a.

The first touch electrode 156a is electrically connected with the first touch line 146 via an opening 181a. The first touch line 146 is provided on a first insulating surface (e.g., on a gate insulating layer 143 described below), namely, at the same level as the scanning line 145a. Similarly, the second touch electrode 156b is electrically connected with the second touch line 148 via an opening 181b. The second touch line 148 is provided on a second insulating surface (e.g., on an insulating layer 149 described below), namely, at the same level as the signal line 147a. The first touch electrode 156a and the second touch electrode 156b are provided on a third insulating surface (e.g., on an insulating layer 154 described below). In each of four corner regions where two first touch electrodes 156a and two second touch electrodes 156b are close to each other, an opening 161 of a counter electrode 160 described below is provided.

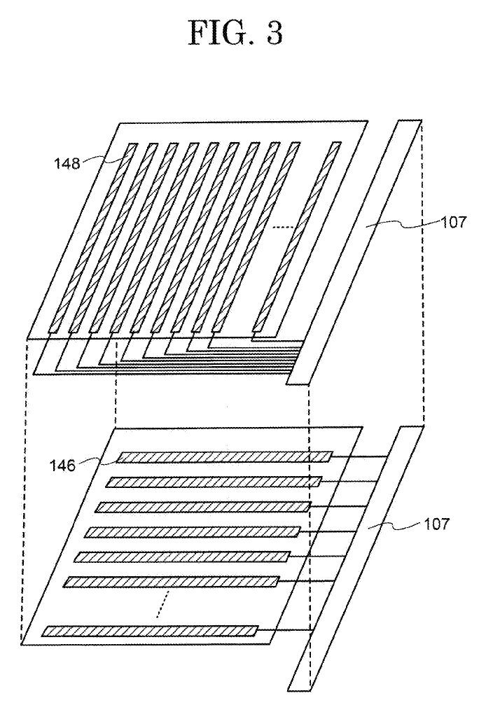

As shown in FIG. 3, the display device 10 includes the first touch lines 146 and the second touch lines 148 in different layers. A direction in which the first touch lines 146 extend and a direction in which the second touch lines 148 extend are perpendicular to each other. The direction in which the first touch lines 146 extend and the direction in which the second touch lines 148 extend are not limited to being perpendicular to each other. The direction in which the first touch lines 146 extend and the direction in which the second touch lines 148 extend may have an angle other than 90 degrees, or may be generally perpendicular to each other, in accordance with the manufacturing method. The expression “generally perpendicular” refers to that two elements have an angle of 80 degrees or greater and less than 90 degrees.

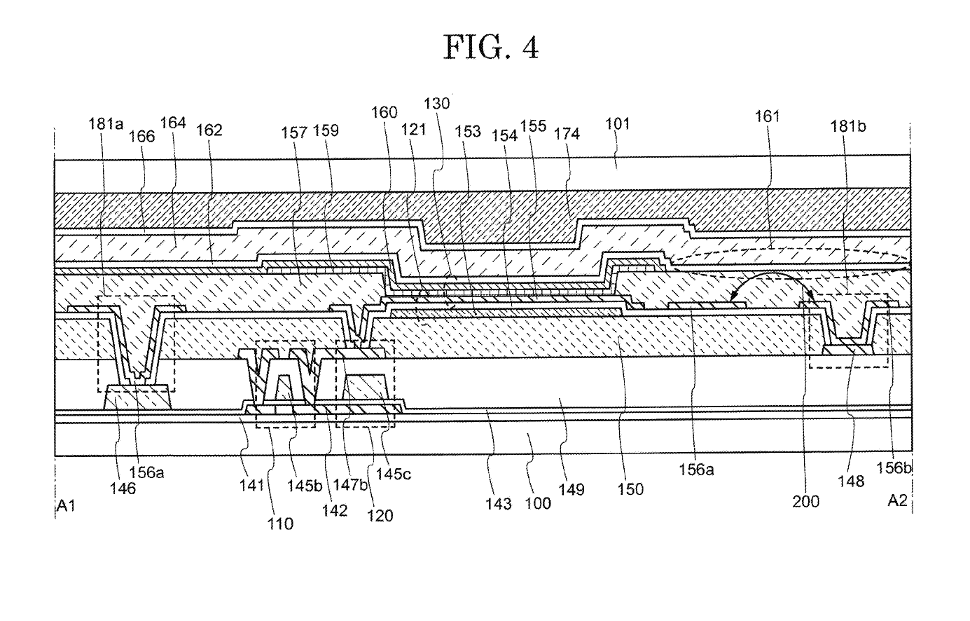

FIG. 4 shows a cross-sectional structure of the display device 10. FIG. 4 is a cross-sectional view of the display region 103a1 taken along line A1-A2 in FIG. 2.

### (1-2. Structure of the Transistor)

As shown in FIG. 4, a transistor 110 includes a semiconductor layer 142, the gate insulating layer 143, a gate electrode layer 145b, and a source/drain electrode layer 147b. The transistor 110 has a top gate/top contact structure. The transistor 110 is not limited to having such a structure, and may have a bottom gate structure or a bottom contact structure.

A capacitance element 120 is a region where a source or drain region of the semiconductor layer 142 and a capacitor electrode layer 145c overlap each other while having the gate insulating layer 143 acting as a dielectric layer therebetween. A capacitance element 121 is a region where a conductive layer 153 and the pixel electrode 155 overlap each other while having the insulating layer 154 acting as a dielectric layer therebetween.

A light emitting element 130 includes the pixel electrode 155, an organic EL layer 159 and the conductive layer 160. The light emitting element 130 has a so-called top emission structure, in which light emitted by the organic EL layer 159 is output toward the counter electrode 160. The light emitting element 130 is not limited to having a top emission structure, and may have a bottom emission structure.

The substrate 100 and a substrate 101 are each formed of glass or an organic resin material.

An insulating layer 141 is provided on the substrate 100 and acts as an underlying layer. The insulating layer 141, with this function, may suppress impurities, typically, an alkaline metal material, water, hydrogen or the like from being diffused from the substrate 100 into the semiconductor layer 142.

The semiconductor layer 142 is provided on the insulating layer 141, and is formed of silicon, an oxide semiconductor, an organic semiconductor or the like.

The gate insulating layer 143 is provided on the insulating layer 141 and the semiconductor layer 142. The gate insulating layer 143 may be formed of silicon oxide, silicon oxide nitride, silicon nitride or any other inorganic material having a high dielectric constant.

The gate electrode 145b is provided on the gate insulating layer 143, and is connected with the scanning line 145a shown in FIG. 1B. The capacitance electrode 145c is provided on the gate insulating layer 143, like the gate electrode 145b. The gate electrode 145b and the capacitance electrode 145c are each formed of a conductive material selected from tantalum, tungsten, titanium, molybdenum, aluminum and the like. The gate electrode 145b and the capacitance electrode 145c may have a single layer structure or a stack structure formed of any of the above-listed conductive materials.

The insulating layer 149 is formed of substantially the same material as any of those usable for the gate insulating layer 143, and is provided on the gate insulating layer 143, the gate electrode 145b and the capacitance electrode 145c. The insulating layer 149 may have a single layer structure or a stack structure formed of any of the above-listed materials.

The source/drain electrode 147b is provided on the insulating layer 149, and is connected with the signal line 147a shown in FIG. 1B. The source/drain electrode 147b is formed of substantially the same material as any of those usable for the gate electrode 145b. The source/drain electrode 147b may be formed of the same material as, or a different material from, that of the gate electrode 145b. The conductive layer in which the source/drain electrode 147b is provided is also used to form other lines. Therefore, this conductive layer needs to, for example, have a low resistance and join well with the semiconductor layer 142.

An insulating layer 150 has a function of a flattening layer, and is provided on the insulating layer 149 and the source/drain electrode 147b. The insulating layer 150 is mainly formed of an organic insulating material such as acrylic resin or the like. Although not shown, the insulating layer 150 may have a stack structure of, for example, an organic insulating material and an inorganic insulating material.

The conductive layer 153 is provided on the insulating layer 150. The conductive layer 153 may be formed of the same material as, or a different material from, that of the gate electrode 145b. Although not shown, the conductive layer in which the conductive layer 153 is provided is also used to form other lines joined with the source/drain electrode 147b. Therefore, this conductive layer needs to, for example, have a low resistance and joins well with the conductive material used to form the source/drain electrode 147b.

The insulating layer 154 is provided on the insulating layer 150 and the conductive layer 153, and is formed of substantially the same material as any of those usable for the gate insulating layer 143.

The pixel electrode 155 has a function of an anode of the display element 130, and preferably has a property of reflecting light. Preferable examples of material for the former function include oxide conductive materials such as ITO (Indium Tin Oxide), IZO (Indium Zinc Oxide) and the like. Preferable examples of material for the latter function include conductive materials having a high surface reflectance such as aluminum, silver and the like. In order to provide both of the functions, the pixel electrode 155 is formed of a stack structure of the above-described materials, specifically, a stack structure including a conductive layer having a high surface reflectance formed of aluminum, silver or the like and an oxide conductive layer formed of ITO, IZO or the like provided on the conductive layer.

The organic EL layer 159 is provided on the pixel electrode 155, and contains a light emitting material such as an organic electroluminescence material or the like.

The counter electrode 160 has a function of a cathode of the display element 130, and is provided for the plurality of pixel electrodes 155 so as to cover the plurality of pixel electrodes 155. The counter electrode 160 is formed of a material that is conductive and light-transmissive in order to transmit light emitted by the organic EL layer 159. The opening 161 is provided in the counter electrode 160.

In addition to being light-transmissive, the counter electrode 160 needs to be reflective in order to form a microcavity with a reflective surface of the pixel electrode 155. Therefore, the counter electrode 160 is formed as a semi-transmissive film.

Specifically, the counter electrode 160 is formed of silver, magnesium or an alloy thereof and has such a thickness of as to transmit light.

A bank layer 157 is formed of an organic resin material to cover a periphery of the pixel electrode 155 and to form a smooth step at an edge of the pixel electrode 155.

The bank layer 157 may be formed of an organic resin material containing a black pigment in order to increase the contrast of a displayed image.

An inorganic insulating layer 162, an organic insulating layer 164 and an inorganic insulating layer 166 are sequentially stacked in this order and act as a sealing layer. The inorganic insulating layer 162 and the inorganic insulating layer 166 are formed of substantially the same material as any of those usable for the gate insulating layer 143. The organic insulating layer 164 is formed of substantially the same material as any of those usable for the insulating layer 150 or the bank layer 157.

An adhesive layer 174 may be formed of an inorganic material, an organic material, or a composite material of an organic material and an inorganic material.

As shown in FIG. 4, the gate electrode 145b and the first touch line 146 are both provided on the gate insulating layer 143. The source/drain electrode 147b and the second touch line 148 are both provided on the insulating layer 149. The first touch electrode 156a, the second touch electrode 156b and the pixel electrode 155 are provided on the insulating layer 154.

### (1-3. Driving of the Touch Sensor)

Now, with reference to FIG. 3 and FIG. 4, the driving of the touch sensor will be described.

As shown in FIG. 3, the first touch line 146 and the second touch line 148 are connected with the driving circuit 107. A voltage is supplied from the driving circuit 107 to the first touch electrode 156a via the first touch line 146, and as a result, an electric field 200 is generated between the first touch electrode 156a and the second touch electrode 156b (see FIG. 4). When, for example, a finger of a human touches the display device 10, the strength of the electric field between the first touch electrode 156a and the second touch electrode 156b is changed. As a result, the inter-line capacitance is changed, and predetermined information is input from the second touch electrode 156b to the driving circuit 107 via the second touch line 148. Thus, position information is detected. In the above example, the finger of the human touches the display device 10. The present invention is not limited to this. For example, when a finger of a human is at a position close to the display device 10, substantially the same effect is provided.

In the structure of this embodiment, the first touch electrode 156a and the second touch electrode 156b are provided in the same layer. Therefore, even a small capacitance change is detected, and thus the detection precision is improved.

As shown in FIG. 4, the counter electrode 160 has the opening 161 in a region overlapping a part of a region adjacent to both of an end of the first touch electrode 156a and an end of the second touch electrode 156b. With such a structure, it is easy to detect a change in the capacitance and thus the function of the touch sensor is still improved.

In the structure of this embodiment, the first touch line 146 and the second touch line 148 are provided in different layers. Therefore, the restrictions on the circuit design are alleviated.

### (2. Method for Manufacturing the Display Device)

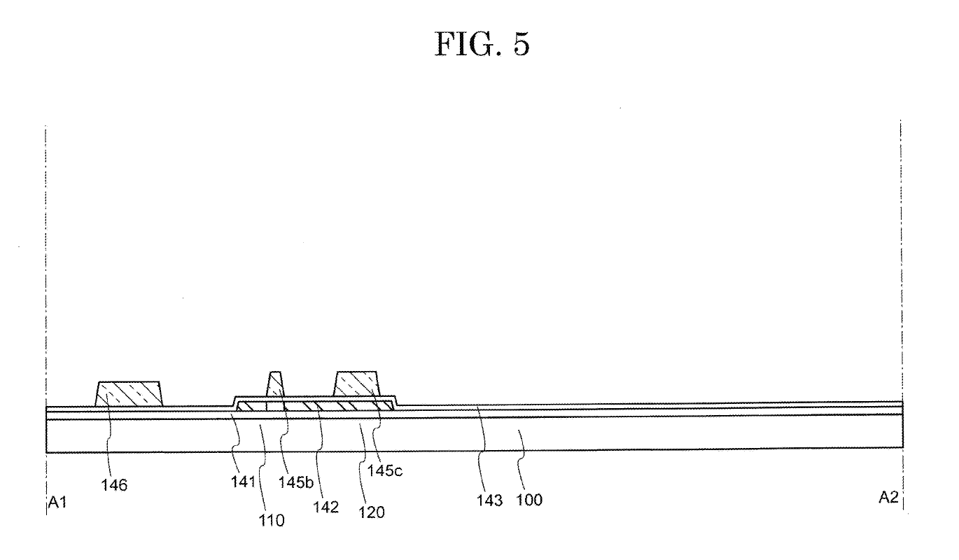

Hereinafter, a method for manufacturing the display device 10 will be described with reference to FIG. 5 to FIG. 11.

### (2-1. Formation of the Transistor)

First, as shown in FIG. 5, the insulating layer 141, the semiconductor layer 142 and the gate insulating layer 143 are formed on a first surface of the substrate 100 (the first surface is a top surface as seen in a cross-sectional view). Then, the gate electrode 145b is formed on the gate insulating layer 143. These layers may each be appropriately formed by photolithography, nanoimprinting, ink-jetting, etching or the like so as to have a predetermined shape.

In the case where, for example, the substrate 100 is to be an organic resin substrate, a polyimide substrate is used. An organic resin substrate may have a thickness of several micrometers to several ten micrometers, so that the display device 100 is a flexible sheet display. The substrate 100 may occasionally need to be transparent to allow light, emitted by the display element 130 (described below), to be output outside. A substrate provided on the side on which the light from the display element 130 is not output does not need to be transparent, and thus may include a metal substrate and an insulating layer formed on the metal substrate.

The insulating layer 141 is formed of silicon oxide, silicon oxide nitride, silicon nitride or the like. The insulating layer 141 may have a single layer structure or a stack structure. The insulating layer 141 may be formed by CVD, spin-coating, printing or the like.

In the case where the semiconductor layer 142 is to be formed of silicon, for example, amorphous silicon, polycrystalline silicon or the like is usable. In the case where the semiconductor layer 142 is to be formed of an oxide semiconductor, for example, a metal material such as indium, gallium, zinc, titanium, aluminum, tin, cerium or the like is usable. The semiconductor layer 142 may be formed of, for example, an oxide semiconductor containing indium, gallium and zinc (IGZO). The semiconductor layer 142 may be formed by sputtering, vapor deposition, plating, CVD or the like.

The gate insulating layer 143 is formed of an insulating film containing at least one of silicon oxide, silicon oxide nitride, silicon nitride, silicon nitride oxide, aluminum oxide, magnesium oxide, hafnium oxide and the like. The gate insulating layer 143 may be formed by substantially the same method as that of the insulating layer 141.

The gate electrode 145b is formed of a metal material selected from tungsten, aluminum, chromium, copper, titanium, tantalum, molybdenum, nickel, iron, cobalt, indium and zinc, an alloy containing one of the above-listed metal materials, an alloy of a combination of any of the above-listed metal materials, or the like. Alternatively, the gate electrode 145b may be formed of any of the above-listed materials containing nitrogen, oxygen, hydrogen or the like. For example, the gate electrode 145b may have a stack structure including an aluminum (Al) layer and a titanium (Ti) layer that are formed by sputtering. At the same time as the gate electrode 145b, the scanning line 145a, the first touch line 146 and the capacitance electrode 145c are formed.

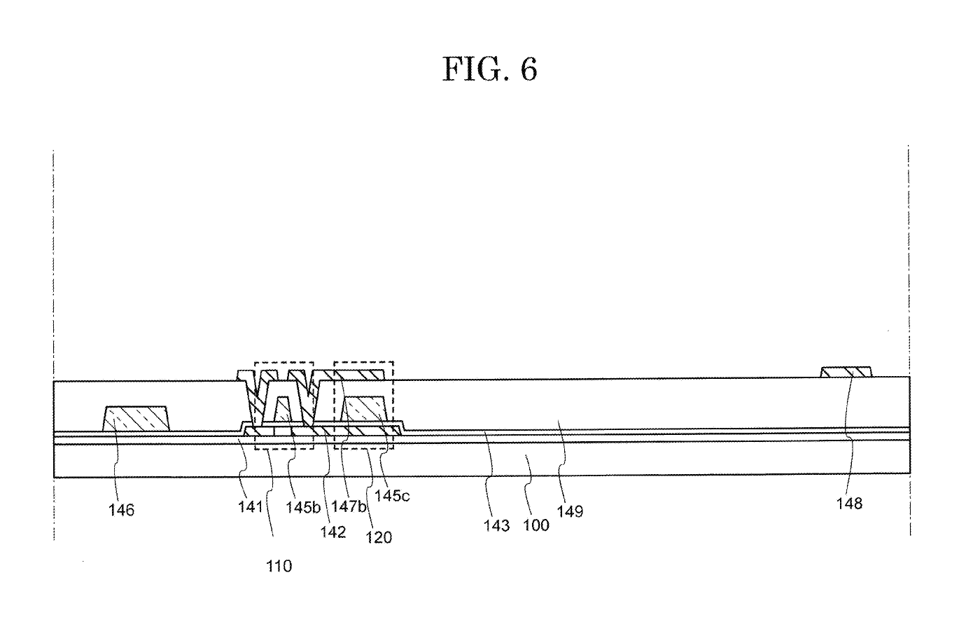

Next, as shown in FIG. 6, the insulating layer 149 is formed on the gate insulating layer 143 and the gate electrode 145b. The insulating layer 149 may be formed of substantially the same material as that of, and by the substantially the same method as that of, the gate insulating layer 143. For example, the insulating layer 149 may be formed of silicon oxide by plasma CVD.

Next, the source/drain electrode 147b is formed on the insulating layer 149 (see FIG. 6). The source/drain electrode 147b may be formed of substantially the same material as that of, and by the substantially the same method as that of, the gate electrode 145b. The source/drain electrode 147b is formed after an opening is formed in the insulating layer 149, and is connected with a source/drain region of the semiconductor layer 142. At the same time as the source/drain electrode 147b, the signal line 147a and the second touch line 148 are formed.

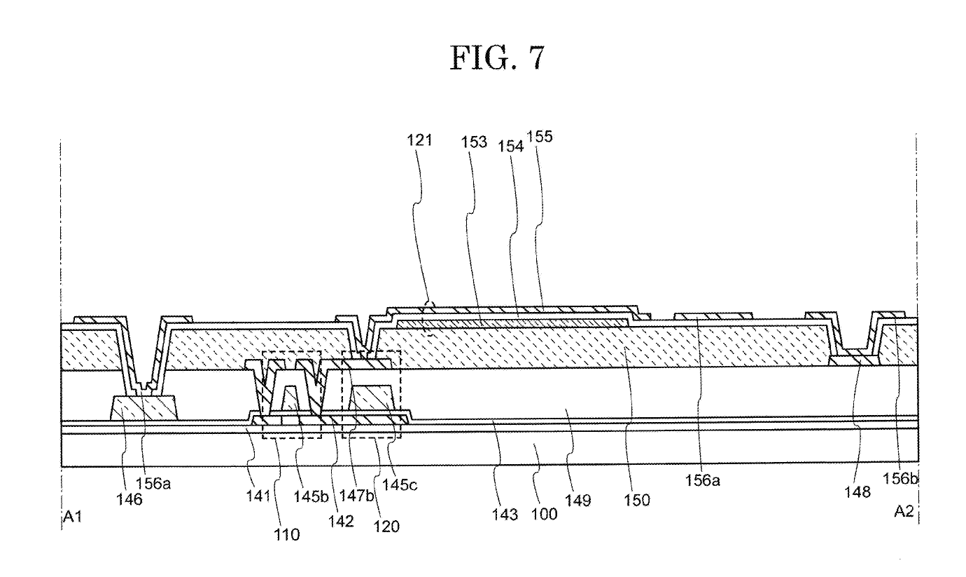

Next, as shown in FIG. 7, the insulating layer 150 is formed on the insulating layer 149 and the source/drain electrode 147b. The insulating layer 150 is formed of an organic insulating material such as acrylic resin, epoxy resin, polyimide or the like. The insulating layer 150 may be formed by spin-coating, printing, ink-jetting or the like.

For example, the insulating layer 150 may be formed of acrylic resin by spin-coating. The insulating layer 150 is formed until having a flat top surface. It is preferable that the insulating layer 150 has a thickness of 1 μm or greater.

### (2-2. Formation of the Display Element)

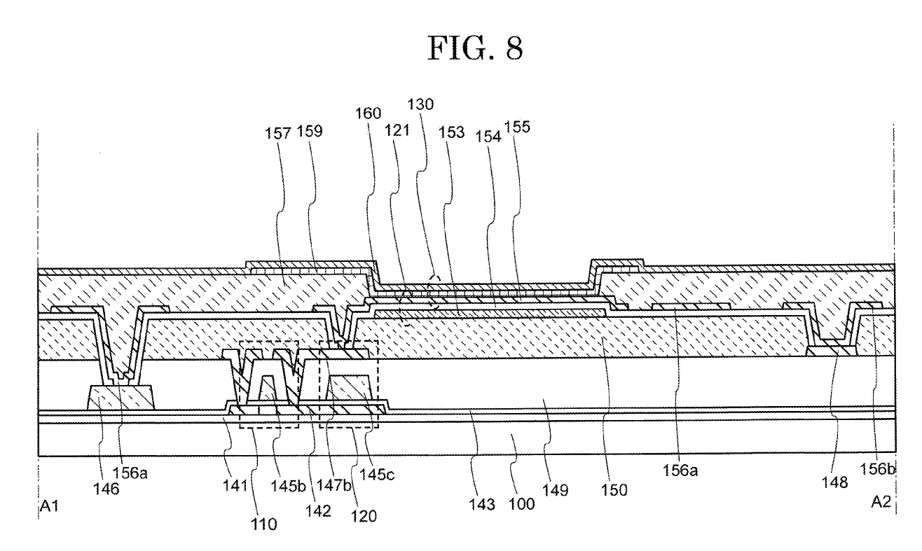

Next, as shown in FIG. 7 and FIG. 8, the following components are formed on the insulating layer 150: the capacitance element 121 (formed to include the conductive layer 153, the insulating layer 154, and the pixel electrode 155), the display element 130 (formed to include the pixel electrode 155, the organic EL layer 159, and the counter electrode 160), and the bank layer 157. Each of the components may be appropriately formed by photolithography, nanoimprinting, ink-jetting, etching or the like so as to have a predetermined shape.

First, the conductive layer 153 is formed on the insulating layer 150. The conductive layer 153 may be formed of substantially the same material as that of, and by substantially the same method as that of, the gate electrode 145b. For example, the conductive layer 153 may be formed of a stack structure of molybdenum, aluminum and molybdenum by sputtering.

Next, the insulating layer 154 is formed on the conductive layer 153. The insulating layer 154 may be formed of substantially the same material as that of, and by substantially the same method as that of, the gate insulating layer 143. For example, the insulating layer 154 may be formed of silicon nitride by plasma CVD.

Next, the pixel electrode 155 is formed on the insulating layer 154 (see FIG. 7). The pixel electrode 155 may be formed of, for example, a light-reflective metal material such as aluminum (Al), silver (Ag) or the like, or may have a stack structure including a transparent conductive layer of ITO or IZO having a high capability of hole injection and a light-reflective metal layer. The pixel electrode 155 may be formed by substantially the same method as that of the gate electrode 145b. For example, the pixel electrode 155 may be formed of a stack structure of ITO, silver and ITO by sputtering.

At the same time as the pixel electrode 155, the first touch electrode 156a and the second touch electrode 156b are formed. The first touch electrode 156a is electrically connected with the first touch line 146 via an opening formed in the insulating layer 149 and the insulating layer 150. Similarly, the second touch electrode 156b is electrically connected with the second touch line 148 via an opening formed in the insulating layer 150.

Next, as shown in FIG. 8, the bank layer 157 is formed on the insulating layer 154 and the pixel electrode 155. An opening is formed in the bank layer 157 to expose a top surface of the pixel electrode 155. It is preferable that an edge of the opening in the bank layer 157 is tapered mildly. For example, the bank layer 157 may be formed of polyimide by spin-coating.

Next, the organic EL layer 159 is formed on the pixel electrode 155 and the bank layer 157. The organic EL layer 159 is formed of a low molecular weight-type or high-molecular weight-type organic material. In the case of being formed of a low molecular weight-type organic material, the organic EL layer 159 may include a light emitting layer containing a light emitting organic material and also include a hole injection layer and an electron injection layer or may further include a hole transfer layer and an electron transfer layer. The hole injection layer and the electron injection layer, or the hole transfer layer and the electron transfer layer, when being included, are provided so as to have the light emitting layer therebetween.

The organic EL layer 159 is formed to at least overlap the pixel electrode 155.

The organic EL layer 159 is formed by, for example, vacuum vapor deposition, printing, spin-coating or the like. In the case of being formed by vacuum vapor deposition, the organic EL layer 159 may be formed by use of a shadow mask optionally, so that the organic EL layer 159 is not formed on the entirety of the bank layer 157. The organic EL layer 159 may be formed of different materials among pixels adjacent to each other, or may be formed of the same material in all the pixels.

Next, as shown in FIG. 8, the counter electrode 160 is formed to cover the pixel electrode 155 and the organic EL layer 159. The counter electrode 160 may be formed of a transparent conductive material such as ITO (indium oxide containing tin oxide), IZO (indium oxide-zinc oxide) or the like, or an alloy of silver and (Ag) and magnesium (Mg). The counter electrode 160 may be formed by vacuum vapor deposition or sputtering. For example, the counter electrode 160 may be formed of IZO by sputtering.

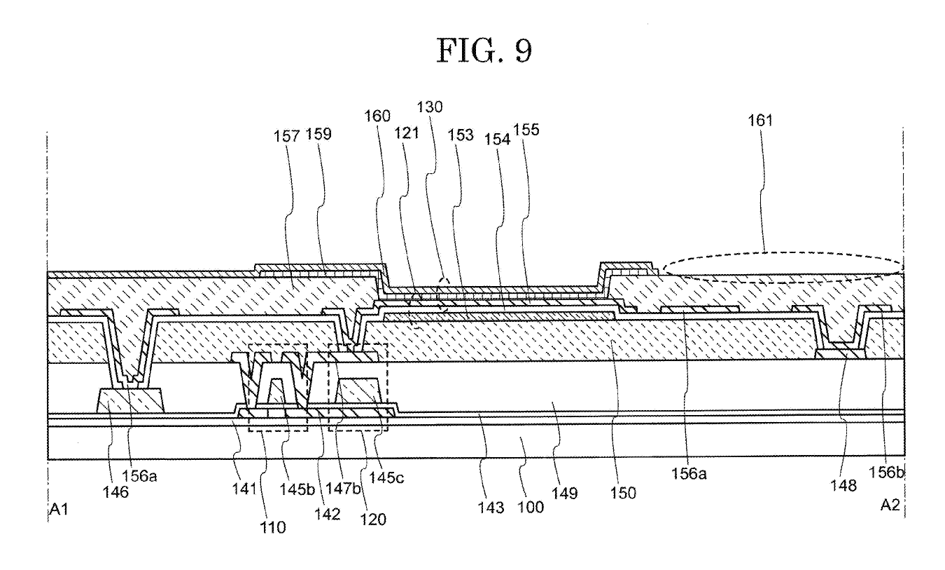

Next, as shown in FIG. 9, the opening 161 is formed in the counter electrode 160. In the case where the opening 161 is to be formed in a region overlapping a part of a region between the first touch electrode 156a and the second touch electrode 156b, a metal mask may be used to partially remove the counter electrode 160. Alternatively, the counter electrode 160 may be formed by ink-jetting so as to have a shape having the opening 161.

### (2-3. Formation of the Sealing Layer)

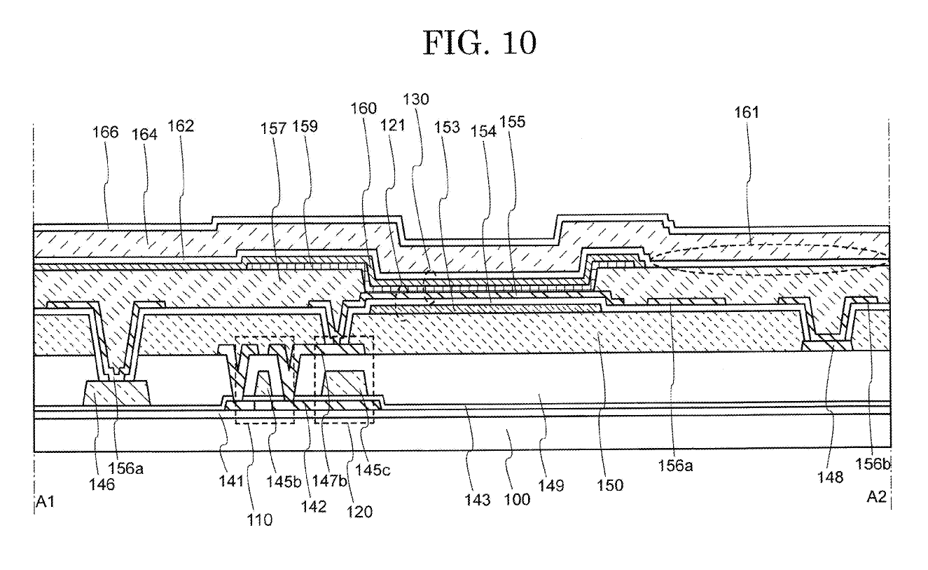

Next, as shown in FIG. 10, the inorganic insulating layer 162, the organic insulating layer 164 and the inorganic insulating layer 166 forming the sealing layer are sequentially formed on the counter electrode 160 and the bank layer 157.

The inorganic insulating layer 162 and the inorganic insulating layer 166 may be formed of an insulating material containing at least one of aluminum oxide, silicon oxide, silicon nitride and the like. It is preferable that the display region 103 is covered with the inorganic insulating layer 162. The inorganic insulating layer 162 and the inorganic insulating layer 166 may each be formed by plasma CVD, thermal CVD, vapor deposition, spin-coating, spraying, or printing. For example, the inorganic insulating layer 162 and the inorganic insulating layer 166 may each be formed of a stack structure of silicon nitride and silicon oxide by plasma CVD. The inorganic insulating layer 162 and the inorganic insulating layer 166 may each have a thickness of several ten nanometers to several micrometers.

The organic insulating layer 164 may be formed of acrylic resin, polyimide resin, epoxy resin or the like. The organic insulating layer 164 may be formed by spin-coating, vapor deposition, spraying, ink-jetting, printing or the like to have a thickness of approximately several micrometers to approximately several ten micrometers.

(2-4. Bonding with the Counter Substrate)

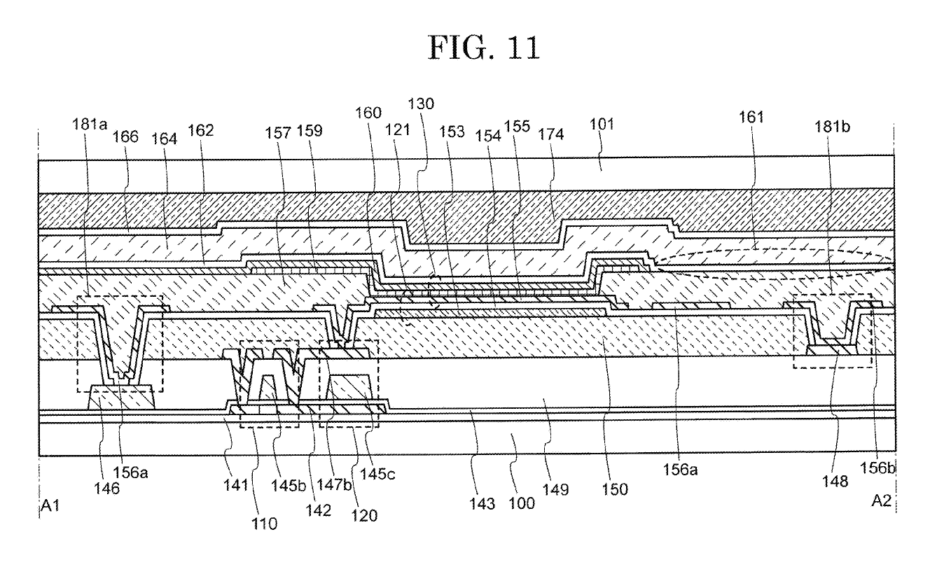

Next, as shown in FIG. 11, the substrate 101 acting as a counter substrate is bonded to the elements formed on the substrate 100 with an adhesive layer 174. The adhesive layer 174 may be formed of, for example, epoxy resin, acrylic resin or the like.

The display device 10 is manufactured by the above-described method. In the structure of this embodiment, the scanning line 145a, the gate electrode 145b and the first touch line 146 are provided in the same layer. The signal line 147b, the source/drain electrode 147b and the second touch line 148 are provided in the same layer. The pixel electrode 155, the first touch electrode 156a and the second touch electrode 156b are provided in the same layer. Because of such a structure, no additional step is required to form the touch sensor. Therefore, the process load imposed in the manufacturing of the display device 10 is suppressed, and the detection precision is improved.

In this embodiment, the first touch line 146 and the second touch line 148 are respectively provided on the insulating layer 143 and the insulating layer 149. The present invention is not limited to this. For example, the first touch line 146 or the second touch line 148 may be provided on another insulating layer. Alternatively, such structures may be combined together.

In this embodiment, the opening 161 is formed in the counter electrode 160. The present invention is not limited to this. For example, it may not be necessary that the counter electrode 160 has the opening 161 formed therein.

In this embodiment, the first direction and the second direction are perpendicular to each other. The present invention is not limited to this. For example, the first direction and the second direction may cross each other at an angle other than 90 degrees.

In this embodiment, the pixel electrode 155, the first touch electrode 156a and the second touch electrode 156b are provided on the same insulating layer, specifically, on the insulating layer 154. The present invention is not limited to this. For example, the first touch electrode 156a and the second touch electrode 156b may be provided on an insulating layer different from the layer on which the pixel electrode 155 is provided.

### Embodiment 2

Hereinafter, a display device including a touch sensor having a different shape as that in embodiment 1 will be described with reference to the drawings. Substantially the same elements and substantially the same steps as those in embodiment 1 will not be described again, and the descriptions thereof in embodiment 1 will be incorporated by reference.

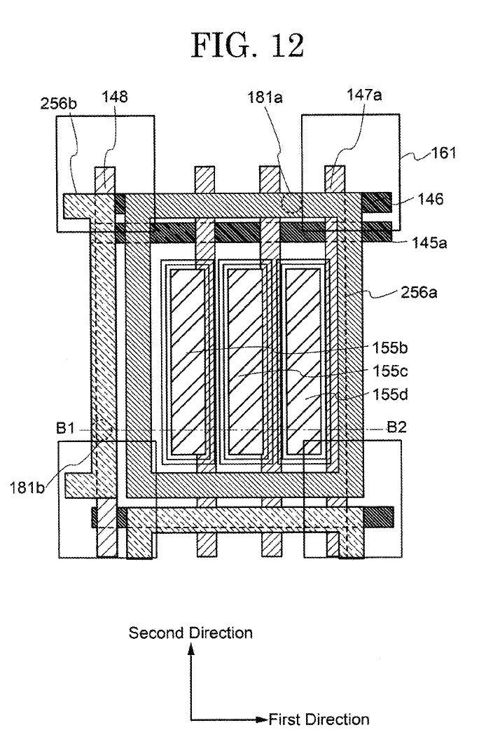

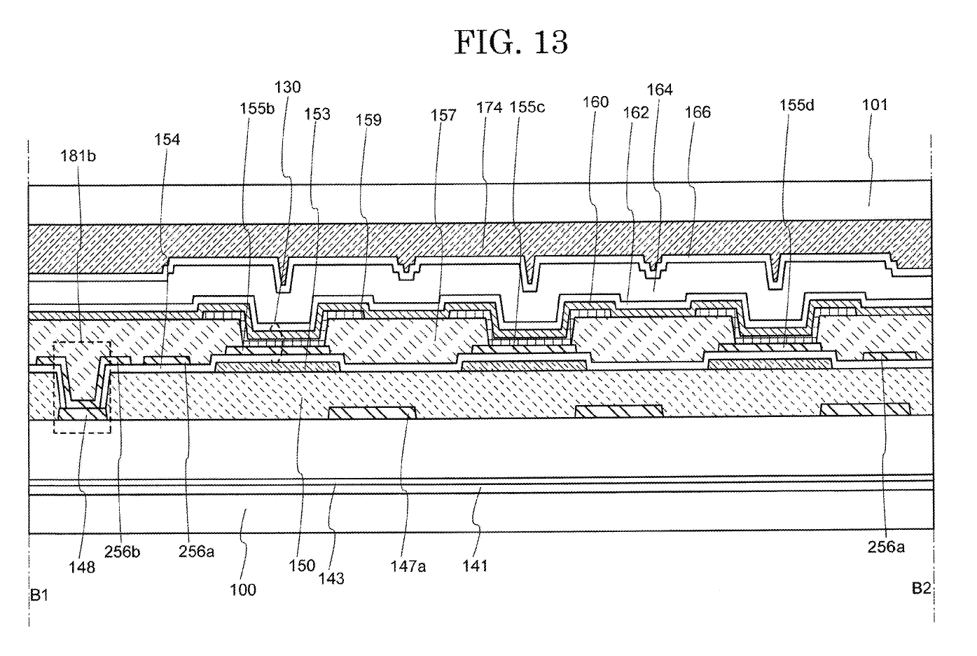

FIG. 12 is an enlarged plan view of the display region 103. FIG. 13 is a cross-sectional view taken along line B1-B2 in FIG. 12. As shown in FIG. 12, a first touch electrode 256a and a second touch electrode 256b may each be provided to surround three pixel electrodes. For example, the first touch electrode 256a surrounds a pixel electrode 155b, a pixel electrode 155c and a pixel electrode 155d.

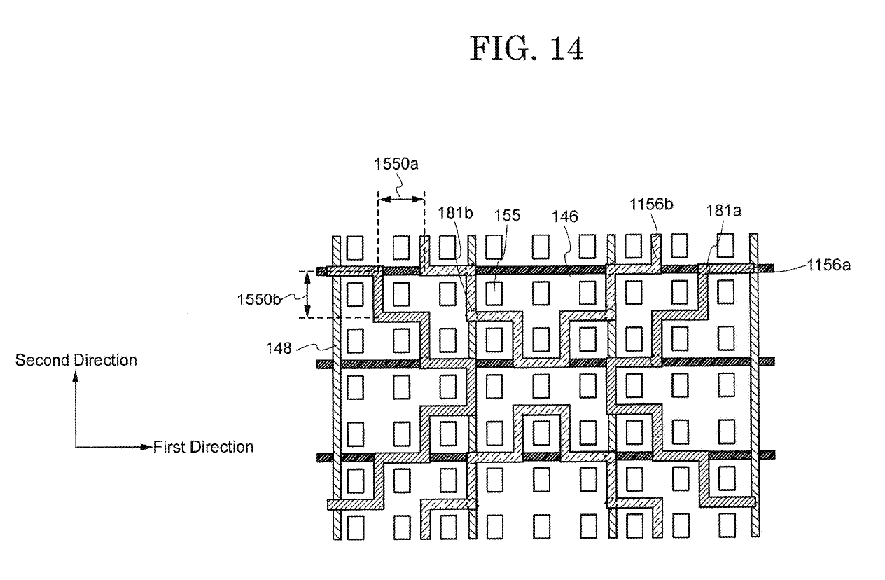

The first touch electrode 256a and the second touch electrode 256b may each be provided to surround a greater number of pixel electrodes. For example, the first touch electrode 256a and the second touch electrode 256b may be provided as shown in FIG. 14. As shown in FIG. 14, for example, three leftmost pixel electrodes in the uppermost row will be discussed. Regarding these three pixel electrodes 155, a distance, in the first direction, from a middle point between two left pixel electrodes 155 to a middle point between two right pixel electrodes 155 is defined as a first pixel electrode pitch 1550a. Three uppermost pixel electrodes in the leftmost column will be discussed. Regarding these three pixel electrodes 155, a distance, in the second direction, from a middle point between two upper pixel electrodes 155 to a middle point between two lower pixel electrodes 155 is defined as a second pixel electrode pitch 1550b. A first touch electrode 1156a includes portions extending in the first direction and each having a length of the first pixel electrode pitch 1550a, and portions extending in the second direction and each having a length of the second pixel electrode pitch 1550b. The portions extending in the first direction and the portions extending in the second direction are connected with each other alternately. With such a structure, the first touch electrode 1156a surrounds a large number of pixel electrodes 155. The second touch electrode 1156b extends with substantially the same shape. In the above-described structure, there are regions where the first touch electrode 1156a and the second touch electrode 1156b are separated from each other in the first direction by the first pixel electrode pitch 1150a, and regions where the first touch electrode 1156a and the second touch electrode 1156b are separated from each other in the first direction by twice the first pixel electrode pitch 1150a. There are regions where the first touch electrode 1156a and the second touch electrode 1156b are separated from each other in the second direction by the second pixel electrode pitch 1150b, and regions where the first touch electrode 1156a and the second touch electrode 1156b are separated from each other in the second direction by twice the second pixel electrode pitch 1150b. In each of such regions, the pixel electrode(s) 155 is(are) located between the first touch electrode 1156a and the second touch electrode 1156b. The pixel electrodes 155 are located in regions not overlapping the first touch electrode 1156a or the second touch electrode 1156b as seen in a plan view.

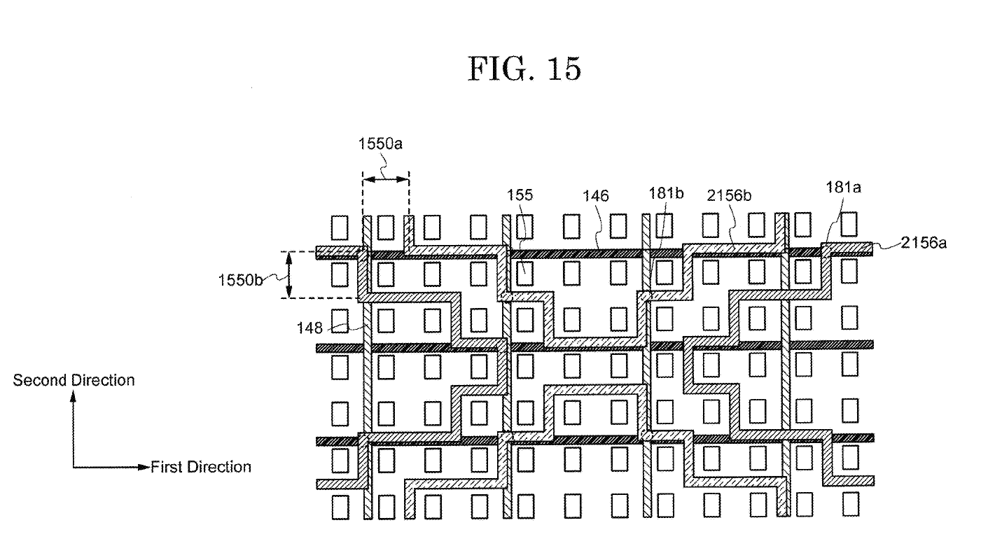

Alternatively, as shown in FIG. 15, a first touch electrode 2156a may include portions extending in the first direction and each having a length of the first pixel electrode pitch 1550a, portions extending in the second direction and each having a length of the second pixel electrode pitch 1550b, and portions extending in the first direction and each having a length of twice the second pixel electrode pitch 1550a. A second touch electrode 2156b may have substantially the same structure. With the above-described structure, there are regions where the first touch electrode 1156a and the second touch electrode 1156b are separated from each other in the first direction by the first pixel electrode pitch 1150a, regions where the first touch electrode 1156a and the second touch electrode 1156b are separated from each other in the first direction by twice the first pixel electrode pitch 1150a, and regions where the first touch electrode 1156a and the second touch electrode 1156b are separated from each other in the first direction by three times the first pixel electrode pitch 1150a. There are regions where the first touch electrode 1156a and the second touch electrode 1156b are separated from each other in the second direction by the second pixel electrode pitch 1150b, and regions where the first touch electrode 1156a and the second touch electrode 1156b are separated from each other in the second direction by twice the second pixel electrode pitch 1150b.

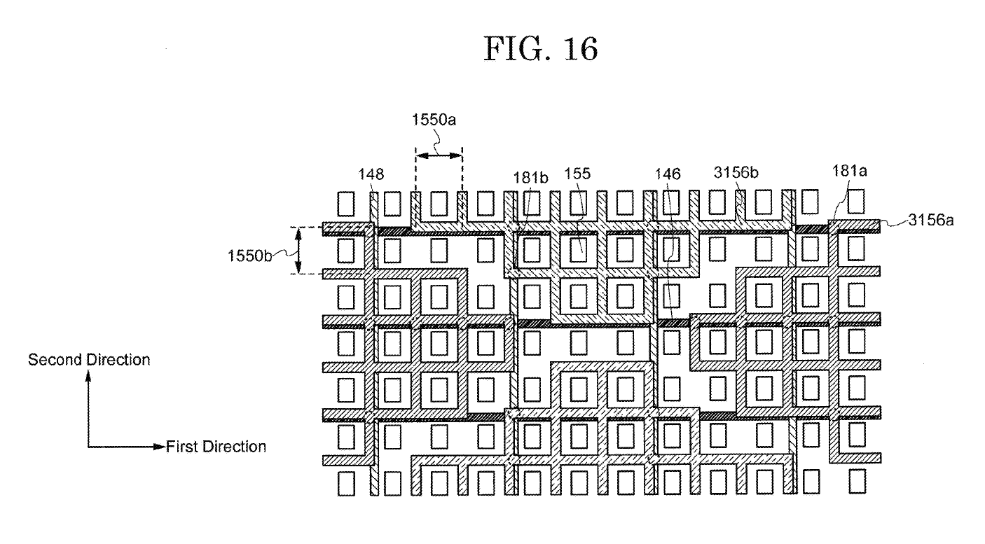

Still alternatively, as shown in FIG. 16, a first touch electrode 3156a and a second touch electrode 3156b each surround each one of the pixel electrodes 155 while having the same shape as that in FIG. 15 in peripheral regions thereof.

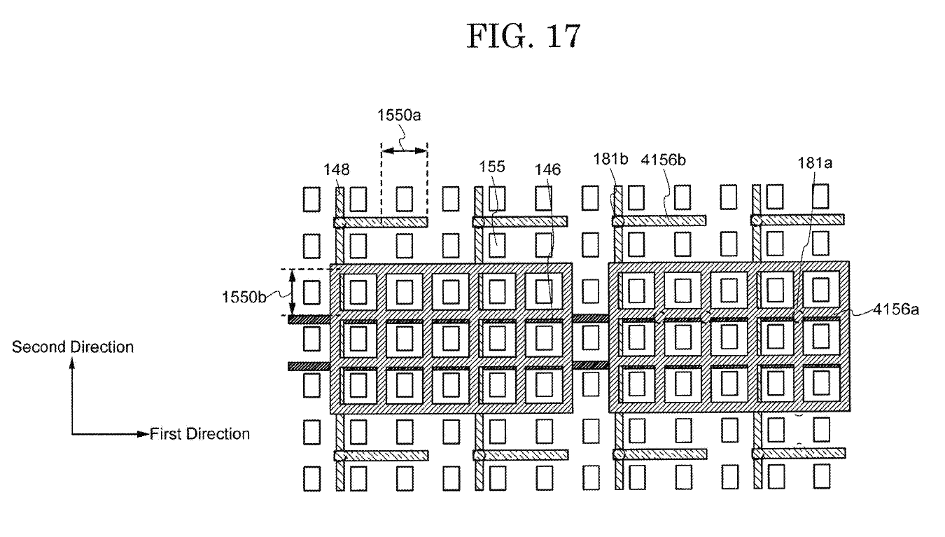

Still alternatively, as shown in FIG. 17, a first touch electrode 4156a may surround each one of the pixel electrodes 155 while including peripheral portions extending in the first direction and each having a length of five times the first pixel electrode pitch 1550a and peripheral portions extending in the second direction and each having a length of three times the second pixel electrode pitch 1550b. The first touch electrode 4156a may have a rectangular outer shape. A second touch electrode 4156b may be separated from the first touch electrode 4156a in the second direction by the second pixel electrode pitch 1150b and may have portions extending in the first direction and each having a length of twice the first pixel electrode pitch 1150a. The portions of the second touch electrode 4156b extending in the first direction may be linear.

With any of the above-described structures, touch sensors of various shapes with an improved detection sensitivity are provided.

In this embodiment, the present invention is applied to an organic EL display device as an example. The present invention is also applicable to a liquid crystal display device, any other self-light emitting display device, an electronic paper-type display device including an electrophoretic display element or the like, or any other flat panel display device. The present invention is applicable to any size of display device from a small or middle display device to a large scale display device, needless to say.

A person of ordinary skill in the art would readily conceive various alterations or modifications of the present invention, and such alterations and modifications are construed as being encompassed in the scope of the present invention. For example, the display devices in the above-described embodiments may have an element added thereto, or deleted therefrom, or may be changed in design optionally by a person of ordinary skill in the art. The methods in the above-described embodiments may have a step added thereto, or deleted therefrom, or may be changed in the condition optionally by a person of ordinary skill in the art. Such devices and methods are encompassed in the scope of the present invention as long as including the gist of the present invention.

What is claimed is:

1. A display device, comprising:
a first insulating surface;
a plurality of scanning lines on the first insulating surface, the plurality of scanning lines extending in a first direction and arrayed in a second direction crossing the first direction;
a second insulating surface on the first insulating surface;
a plurality of signal lines provided on the second insulating surface, the plurality of signal lines extending in a third direction crossing the first direction and arrayed in a fourth direction crossing the third direction;
a plurality of pixel electrodes respectively being in correspondence with intersections of the plurality of scanning lines and the plurality of signal lines;
a plurality of first touch lines on the first insulating surface, the plurality of first touch lines extending in the first direction and arrayed in the second direction;
a plurality of second touch lines on the second insulating surface, the plurality of second touch lines extending in the third direction and arrayed in the fourth direction;
a third insulating surface on the second insulating surface;
a first touch electrode on the third insulating surface, the first touch electrode being between pixel electrodes adjacent to each other as seen in a plan view, among the plurality of pixel electrodes, and electrically connected with at least one of the first touch lines; and
a second touch electrode on the third insulating surface, the second touch electrode being between pixel electrodes adjacent to each other in a plan view, among the plurality of pixel electrodes, and electrically connected with at least one of the second touch lines.

2. The display device according to claim 1, wherein the plurality of pixel electrodes are on the third insulating surface.

3. The display device according to claim 1, wherein
the first touch electrode and/or the second touch electrode each surround at least one of the plurality of pixel electrodes.

4. The display device according to claim 1, wherein
the second insulating surface is on the plurality of scanning lines and the plurality of first touch lines, and
the third insulating surface is on the plurality of signal lines and the plurality of second touch lines.

5. The display device according to claim 1, further comprising:
a counter electrode provided on the plurality of pixel electrodes so as to cover the plurality of pixel electrodes; and
a light emitting layer provided between each of the plurality of pixel electrodes and the counter electrode.

6. The display device according to claim 5, wherein the counter electrode has an opening provided in a region overlapping a part of a region between the first touch electrode and the second touch electrode adjacent to the first touch electrode in a plan view.

7. The display device according to claim 1, wherein one of the plurality of pixel electrodes is in a region not overlapping the first touch electrode or the second touch electrode in a plan view.

8. The display device according to claim 1, wherein
the plurality of scanning lines and the plurality of first touch lines are on the same surface as each other; and
the plurality of signal lines and the plurality of second touch lines are on the same surface as each other.

9. The display device according to claim 1, wherein
the first direction and the second direction are perpendicular to each other; and
the third direction and the fourth direction are perpendicular to each other.

10. The display device according to claim 1, further comprising a bank layer covering edges of the plurality of pixel electrodes and exposing top surfaces of the plurality of pixel electrodes,
wherein the bank layer covers the first touch electrode and the second touch electrode.
